(19) United States
(12) Patent Application Publication
(10) Pub. No.: US 2025/0015564 A1
(43) Pub. Date: Jan. 9, 2025

(54) LIGHT EMISSION DEVICE AND LIGHT SOURCE DEVICE

(71) Applicant: FURUKAWA ELECTRIC CO., LTD., Tokyo (JP)

(72) Inventor: Masaya NAKAZUMI, Tokyo (JP)

(73) Assignee: FURUKAWA ELECTRIC CO., LTD., Tokyo (JP)

(21) Appl. No.: 18/895,499

(22) Filed: Sep. 25, 2024

Related U.S. Application Data
(63) Continuation of application No. PCT/JP2023/008480, filed on Mar. 7, 2023.

(30) Foreign Application Priority Data
Mar. 31, 2022 (JP) 2022-058111

(51) Int. Cl. H01S 5/40; H01S 5/02253

(52) U.S. Cl. CPC H01S 5/4012; H01S 5/02253

(57) ABSTRACT

A light emission device includes: a condenser lens having an optical axis extending in a first direction, the condenser lens being configured to collect light in a second direction orthogonal to the first direction, wherein an array of a plurality of light beams traveling in the first direction and arranged at intervals in the second direction is input to the condenser lens; and a light emission unit group including a plurality of light emission units configured to output the beams included in the array, each of the light emission units being configured to output each of the beams in a single mode in the second direction and in a multi-mode in a third direction orthogonal to the first direction and the second direction.

This application is a continuation of International Application No. PCT/JP2023/008480, filed on Mar. 7, 2023 which claims the benefit of priority of the prior Japanese Patent Application No. 2022-058111, filed on Mar. 31, 2022, the entire contents of which are incorporated herein by reference.

### BACKGROUND

The present disclosure relates to a light emission device and a light source device.

In the related art, semiconductor laser modules including a plurality of chip-on-submounts have been known (e.g., JP 2016-164671 A). In a semiconductor laser module disclosed in JP 2016-164671 A, an array of laser beams output from a plurality of chip-on-submounts are collected by a condenser lens and coupled to an optical fiber. The semiconductor laser module is an example of a light emission device, the chip-on-submount is an example of a light emission unit, and the optical fiber is an example of a coupled portion.

### SUMMARY

As described in JP 2016-164671 A, a light emission device having a configuration in which an array of light beams output from a plurality of light emission units are collected by a condenser lens may have a difference in optical path length from each of the light emission units to the condenser lens.

As a result of intensive study by the inventor, it has been found that a beam having a longer optical path length from the light emission unit to the condenser lens is likely to expand as compared with another beam having a shorter optical path length, reducing coupling efficiency to the coupled portion as compared with the other beam, reducing the overall coupling efficiency of the plurality of beams to the coupled portion.

There is a need for an improved novel light emission device, for example, configured to collect an array of a plurality of light beams by a condenser lens to suppress reduction in overall coupling efficiency of coupling the plurality of beams to a coupled portion, and further to obtain a light source device including the light emission device.

According to one aspect of the present disclosure, there is provided a light emission device including: a condenser lens having an optical axis extending in a first direction, the condenser lens being configured to collect light in a second direction orthogonal to the first direction, wherein an array of a plurality of light beams traveling in the first direction and arranged at intervals in the second direction is input to the condenser lens; and a light emission unit group including a plurality of light emission units configured to output the beams included in the array, each of the light emission units being configured to output each of the beams in a single mode in the second direction and in a multi-mode in a third direction orthogonal to the first direction and the second direction, wherein an optical path length between the condenser lens and the light emission unit outputting the beam is longer as the beam output from the light emission unit is farther from the beam positioned at an end of the array in a direction opposite to the second direction, wherein a center line positioned at a center in the second direction of the array of the beams output from the plurality of light emission units included in the light emission unit group is shifted in a direction opposite to the second direction relative to the optical axis of the condenser lens.

### BRIEF DESCRIPTION OF THE DRAWINGS

FIG. 1 is an exemplary schematic plan view of an optical device according to a first embodiment;

FIG. 2 is an exemplary schematic perspective view of a base included in the optical device of the first embodiment;

FIG. 3 is an exemplary schematic side view of a subunit included in the optical device of the first embodiment;

FIG. 4 is an exemplary schematic side view of an array of light beams input to a condenser lens of the optical device of the first embodiment;

FIG. 5 is an exemplary schematic cross-sectional view of the array of light beams input to the condenser lens of the optical device of the first embodiment;

FIG. 6 is an exemplary schematic side view of an optical system included in an optical device according to a second embodiment;

FIG. 7 is an exemplary schematic side view of an optical system included in an optical device according to a third embodiment;

FIG. 8 is an exemplary schematic side view of an optical system included in an optical device according to a fourth embodiment;

FIG. 9 is an exemplary schematic plan view of an optical device according to a fifth embodiment;

FIG. 10 is an exemplary schematic plan view of an optical device according to a sixth embodiment;

FIG. 11 is an exemplary schematic perspective view of an optical device according to a seventh embodiment; and

FIG. 12 is an exemplary configuration diagram of a light source device according to an eighth embodiment.

### DETAILED DESCRIPTION

Exemplary embodiments will be disclosed below. The configurations of the embodiments described below, and the functions and results (effects) provided by the configurations are provided as an example. The present disclosure may also be achieved by configurations other than those disclosed in the following embodiments. In addition, according to the present disclosure, it is possible to obtain at least one of various effects (including derivative effects) obtained by the configurations.

The embodiments described below include similar configurations. Therefore, according to the configurations of the respective embodiments, similar functions and effects based on the similar configurations may be obtained. In addition, in the following, the similar configurations are denoted by similar reference numerals, and redundant description thereof may be omitted.

In the present description, ordinal numbers are given for convenience of distinction between components, portions, directions, and the like, not indicating priority or sequence.

Furthermore, in the drawings, an X1-direction is indicated by an arrow X1, an X2-direction is indicated by an arrow X2, a Y-direction is indicated by an arrow Y, and a Z-direction is indicated by an arrow Z. The X1-direction, the Y-direction, and the Z-direction intersect each other and are orthogonal to each other. Furthermore, the X1-direction and the X2-direction extend opposite to each other.

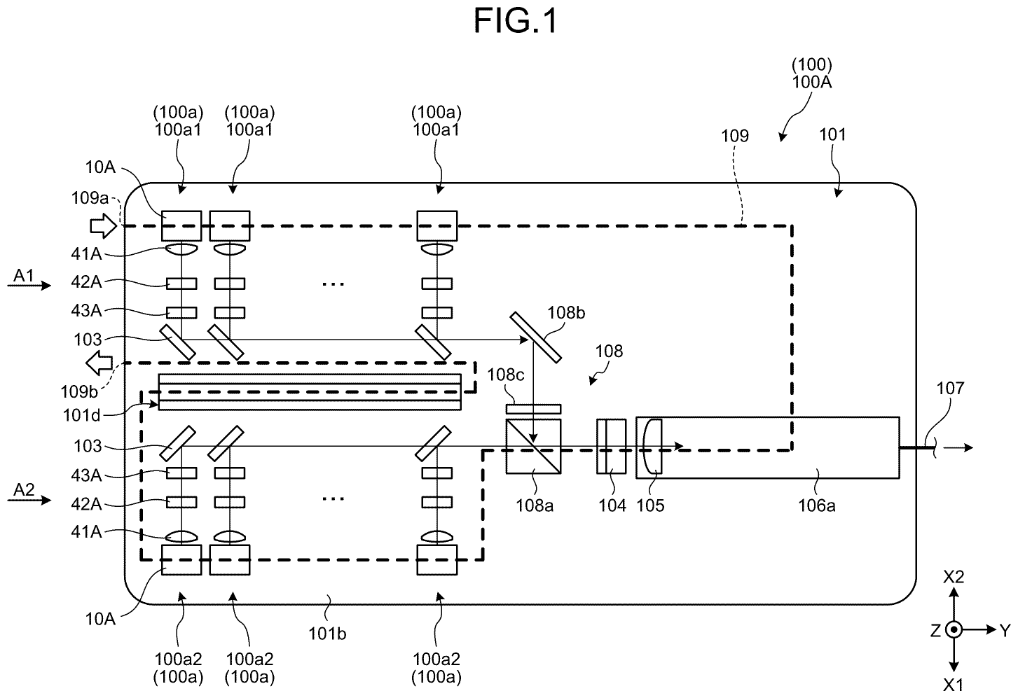

Note that in FIGS. 1, 3, 4, and 6 to 10, an optical path of (the beam of) laser light is indicated by a solid arrow.

FIG. 1 is a schematic configuration diagram of a light emission device 100A (100) according to a first embodiment, and is a plan view of the inside of the light emission device 100A as viewed in a direction opposite to the Z-direction.

As illustrated in FIG. 1, the light emission device 100A includes a base 101, a plurality of subunits 100a, a light combining unit 108, condenser lenses 104 and 105, and an optical fiber 107. Each of the subunits 100a includes a light emission unit 10A from which laser light is output, the output laser light is transmitted to an end portion (not illustrated) of the optical fiber 107 via a mirror 103, the light combining unit 108, and the condenser lenses 104 and 105 of each subunit 100a, and is optically coupled to the optical fiber 107.

The base 101 is made of a material having high thermal conductivity, such as a copper-based material or an aluminum-based material. The base 101 may include one component or a plurality of components. The base 101 is covered with a cover (not illustrated). The plurality of subunits 100a, a plurality of the mirrors 103, the light combining unit 108, the condenser lenses 104 and 105, and the optical fiber 107 each have an end portion that is provided on the base 101 and stored in a storage chamber (not illustrated) formed between the base 101 and the cover. The storage chamber is hermetically sealed.

The optical fiber 107 is an output optical fiber, and is fixed to the base 101 via a fiber support portion 106a that supports an end portion of the optical fiber.

The fiber support portion 106a may be configured as a part of the base 101, integrally with the base 101, or the fiber support portion 106a configured as a separate member from the base 101 may be mounted to the base 101 via a fastener such as a screw.

Each of the subunits 100a includes the light emission unit 10A that outputs laser light, a plurality of lenses 41A to 43A, and the mirror 103. The lenses 41A to 43A and the mirror 103 are an example of an optical component. The lenses 42A and 43A collimate the laser light along a fast axis and a slow axis.

In addition, the light emission device 100A includes two arrays A1 and A2 in which pluralities of subunits 100a are arranged at predetermined intervals in the Y-direction. In a subunit 100al (100a) of the array A1, the light emission unit 10A outputs laser light in the X1-direction, the lenses 41A to 43A transmit the laser light from the light emission unit 10A in the X1-direction, and the mirror 103 reflects the laser light traveling in the X1-direction in the Y-direction. Meanwhile, in a subunit 100a2 (100a) of the array A2, the light emission unit 10A outputs laser light in the X2-direction, the lenses 41A to 43A transmit the laser light from the light emission unit 10A in the X2-direction, and the mirror 103 reflects the laser light traveling in the X2-direction in the Y-direction.

In the present embodiment, the subunit 100al of the array A1 and the subunit 100a2 of the array A2 are arranged in the X1-direction (X2-direction). When the subunit 100al and the subunit 100a2 are arranged in the X1-direction, for example, the size of the light emission device 100A in the Y-direction is advantageously reduced. However, the present disclosure is not limited to this arrangement, and the subunits 100al and the subunits 100a2 may be staggered. For example, each of the subunit 100a2 may be arranged in the X1-direction so as to be positioned in a gap between two subunits 100al adjacent in the Y-direction.

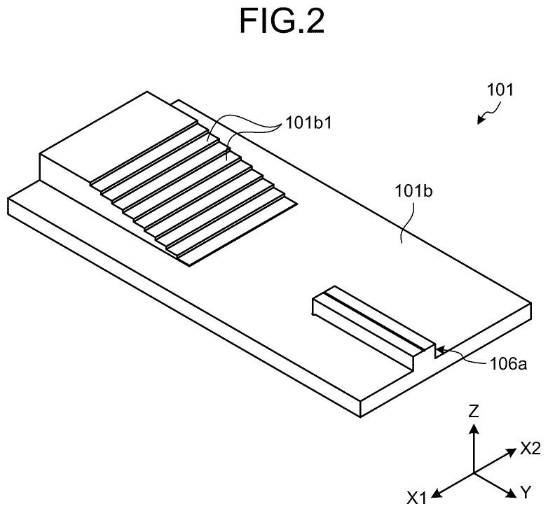

FIG. 2 is a perspective view of the base 101. As illustrated in FIG. 2, the base 101 has a surface 101b that is provided with a plurality of steps 101b1 (stepped surface) along which the positions of the subunits 100a are shifted in a direction opposite to the Z-direction toward the Y-direction. In each of the arrays A1 and A2 in which the pluralities of subunits 100a are arranged at the predetermined intervals (e.g., constant intervals) in the Y-direction, each subunit 100a are provided on each of the steps 101b1. Therefore, the positions of the subunits 100a in the array A1 in the Z-direction are shifted in the direction opposite to the Z-direction toward the Y-direction, and the positions of the subunits 100a in the array A2 in the Z-direction are also shifted in the direction opposite to the Z-direction toward the Y-direction. Such a configuration makes it possible to input parallel laser light traveling in the Y-direction and arranged in the Z-direction, from the plurality of mirrors 103 to the light combining unit 108, in each of the arrays A1 and A2. Note that in the array A1, the light emission units 10A are arranged in an array in a direction between the Y-direction and the direction opposite to the Z-direction, and in the array A2, the light emission units 10A are arranged in an array in a direction between the Y-direction and the direction opposite to the Z-direction. In other words, in the array A1, the plurality of light emission units 10A is arranged to be shifted from each other in the Z-direction, and in the array A2, the plurality of light emission units 10A is arranged to be shifted from each other in the Z-direction.

As illustrated in FIG. 1, the laser light from the mirrors 103 is input to the light combining unit 108 and combined in the light combining unit 108.

The light combining unit 108 includes a combiner 108a, a mirror 108b, and a half wave plate 108c. The combiner 108a, the mirror 108b, and the half wave plate 108c are an example of the optical component.

The mirror 108b directs the laser light from the subunit 100a of the array A1 toward the combiner 108a via the half wave plate 108c. The half wave plate 108c rotates a polarization plane of the light from the array A1 by 90°.

Meanwhile, the laser light from the subunit 100a of the array A2 is directly input to the combiner 108a. Therefore, the polarization plane of the laser light from the subunit 100a of the array A2 and the polarization plane of the laser light from the subunit 100a of the array A1 are orthogonal to each other.

The combiner 108a combines the laser light from the two arrays A1 and A2. The combiner 108a is also referred to as a polarization beam combining element.

The laser light from the combiner 108a is collected toward the end portion (not illustrated) of the optical fiber 107 by the condenser lenses 104 and 105, optically coupled to the optical fiber 107, and transmitted in the optical fiber 107. The condenser lens 104 collects the laser light in the Z-direction. Here, collecting the laser light in the Z-direction means directing the laser light separated from an optical axis of the condenser lens 104 in the Z-direction to a focal point on the optical axis. The condenser lens 105 collects the laser light in the X1-direction or the X2-direction. Here, collecting the laser light in the X1-direction or the X2-direction means directing the laser light separated from the optical axis of the condenser lens 104 in the X1-direction or the X2-direction to the focal point on the optical axis. The condenser lenses 104 and 105 are an example of the optical component.

In addition, the base 101 is provided with a coolant passage 109 that cools the subunits 100a (light emission units 10A), the fiber support portion 106a, the condenser lenses 104 and 105, the combiner 108a, a shielding wall 101d (described later), and the like. In the coolant passage 109, for example, a coolant such as a coolant flows. The coolant passage 109 extends, for example, near a mounting surface of each component of the base 101, or, immediately below or in the vicinity the mounting surface, and an inner surface of the coolant passage 109 and the coolant (not illustrated) in the coolant passage 109 are thermally connected to components or portions to be cooled, that is, the subunits 100a (light emission units 10A), the fiber support portion 106a, the condenser lenses 104 and 105, the combiner 108a, and the like. Heat exchange is performed between the coolant and the components or portions via the base 101, and the components are cooled. Note that, as an example, an inlet 109a and an outlet 109b of the coolant passage 109 are provided at an end of the base 101 in the direction opposite to the Y-direction, but may be provided at other positions.

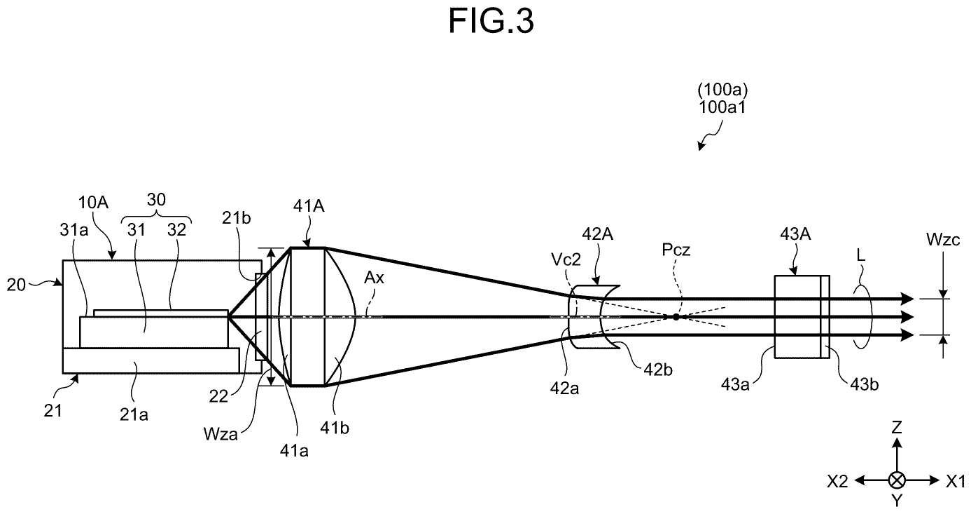

FIG. 3 is a side view illustrating a configuration of the subunit 100al (100a) of the array A1. Note that in the subunit 100a2 of the array A2, arrangement of the optical components and a transmission direction of the laser light are opposite to those of the subunit 100al, but the subunit 100a2 has a configuration similar to the subunit 100al.

The light emission unit 10A includes a chip-on-submount 30 and a case 20 that stores the chip-on-submount 30. Note that, in FIG. 3, the light emission unit 10A is drawn as viewed through the case 20.

The case 20 is a rectangular parallelepiped box, and stores the chip-on-submount 30. The case 20 includes a wall member 21 and a window member 22. The wall member 21 is made of, for example, a metal material.

The case 20 includes a base 21a. The base 21a has a plate shape intersecting the Z-direction. The base 21a is, for example, a part (bottom wall) of the wall member 21. The base 21a is made of, for example, a metal material having high thermal conductivity, such as oxygen-free copper. The oxygen free-copper is an example of the copper-based material. Note that the base 21a may be provided separately from the wall member 21.

The wall member 21 is provided with an opening portion 21b at an end in the X1-direction. The opening portion 21b is mounted with the window member 22 that transmits laser light L. The window member 22 intersects with and is orthogonal to the X1-direction. The laser light L output from the chip-on-submount 30 in the X1-direction passes through the window member 22 to the outside the light emission unit 10A. The laser light L is output from the light emission unit 10A in the X1-direction.

A boundary portion between a plurality of members (not illustrated) constituting the wall member 21 (case 20), a boundary portion between the wall member 21 and the window member 22, and the like are sealed to prevent passage of a gas. In other words, the case 20 is hermetically sealed. Note that the window member 22 is also a part of the wall member 21.

The chip-on-submount 30 includes a submount 31 and a light emitting element 32.

The submount 31 has, for example, a plate shape intersecting the Z-direction and orthogonal to the Z-direction. The submount 31 may be made of an insulating material having relatively high thermal conductivity, such as aluminum nitride, ceramic, or glass. On the submount 31, a metallized layer 31a is formed as an electrode to supply electric power to the light emitting element 32.

The submount 31 is mounted on the base 21a. The light emitting element 32 is mounted on a top surface of the submount 31. In other words, the light emitting element 32 is mounted on the base 21a via the submount 31, and is mounted on the base 101 via the submount 31 and the case 20.

The light emitting element 32 is, for example, a semiconductor laser element having a fast axis (FA) and a slow axis (SA). The light emitting element 32 has an elongated shape extending in the X1-direction. The light emitting element 32 outputs the laser light L in the X1-direction from an output opening (not illustrated) provided at an end in the X1-direction. The chip-on-submount 30 is mounted so that the fast axis of the light emitting element 32 extends in the Z-direction and the slow axis extends in the Y-direction. The Z-direction is an example of a fast axis direction, and the Y-direction is an example of a slow axis direction.

The light emitting element 32 outputs the laser light L having a wavelength of, for example, 400 [nm] or more and 1200 [nm] or less. Furthermore, the laser light L is output from the light emitting element 32 in a single mode in the fast axis direction (Z-direction) and is output in a multi-mode in the slow axis direction (Y-direction).

The laser light L output from the light emitting element 32 passes through the lens 41A, the lens 42A, and the lens 43A in this order, and is collimated at least in the Z-direction and the Y-direction. The lens 41A, the lens 42A, and the lens 43A are all provided outside the case 20.

In the present embodiment, the lens 41A, the lens 42A, and the lens 43A are arranged in this order in the X1-direction. The laser light L output from the light emitting element 32 passes through the lens 41A, the lens 42A, and the lens 43A in this order. In addition, the optical axis of the laser light L has a linear shape and extends in the X1-direction or the X2-direction, until the laser light L is emitted from the light emitting element 32 and reaches the mirror 103 through the lens 41A, the lens 42A, and the lens 43A. Furthermore, during passage of the laser light L, the fast axis direction of the laser light L is in the Z-direction, and the slow axis direction of the laser light L is in the Y-direction.

The lens 41A is slightly separated from the window member 22 in the X1-direction or is in contact with the window member 22 in the X1-direction.

The laser light L having passed through the window member 22 is input to the lens 41A. The lens 41A has an optically functional portion, for example, having a symmetric shape about a center axis Ax along the optical axis and further has the shape of a solid of revolution around the center axis Ax. The lens 41A is arranged so that the center axis Ax extends in the X1-direction and overlaps the optical axis of the laser light L. The lens 41A has an input surface 41a and an output surface 41b each of which has a surface of revolution around the center axis Ax extending in the X1-direction. The output surface 41b is a convex curved surface that bulges in the X1-direction. The output surface 41b bulges larger than the input surface 41a. The lens 41A is a so-called convex lens, and is also referred to as a condenser lens.

The laser light L output from the lens 41A has a beam width reduced gradually in the X1-direction. Note that the beam width is a width of a region having an optical intensity that is equal to or larger than a predetermined value in a beam profile of the laser light. The predetermined value is, for example, 1/e² of a peak optical intensity. The lens 41A focuses the laser light L in the Z-direction, the Y-direction, and a direction between the Z-direction and the Y-direction, and therefore an effect of reducing aberration of the laser light L may be obtained.

The lens 42A has a symmetrical shape about a virtual center plane Vc2 as a plane intersecting and orthogonal to the Z-direction. The lens 42A has an input surface 42a and an output surface 42b each of which has a generatrix extending in the Y-direction and has a cylindrical surface extending in the Y-direction. The input surface 42a is a convex curved surface that bulges in a direction opposite to the X1-direction. In addition, the output surface 42b is a concave curved surface that is depressed in the X1-direction.

The lens 42A collimates the laser light L in the Z-direction, that is, along the fast axis, in a state where a beam width Wzc in the Z-direction is smaller than a beam width Wza on the input surface 41a of the lens 41A in the Z-direction. The lens 42A is a concave lens in a cross-section orthogonal to the Y-direction. The lens 42A is also referred to as a collimation lens.

In addition, the lens 42A is positioned closer to the lens 41A relative to a focal point Pcz in the Z-direction of the laser light L passing through the lens 41A. If the lens 42A is positioned farther from the lens 41A relative to the focal point Pcz in the Z-direction, the focal point Pcz in the Z-direction appears on the optical path of the laser light L between the lens 41A and the lens 42A. In this case, there is a possibility that inconvenience, such as accumulation of dust at the focal point Pcz in the Z-direction having a high energy density, occurs. In the present embodiment, the lens 42A is positioned closer to the lens 41A relative to the focal point Pcz in the Z-direction, and therefore, the laser light L is collimated by the lens 42A before reaching the focal point Pcz. In other words, according to the present embodiment, the focal point Pcz in the Z-direction does not appear on the optical path of the laser light L, and therefore, it is possible to avoid occurrence of inconvenience due to the focal point Pcz.

Note that although a focal point (not illustrated) of the laser light L in the Y-direction appears between the lens 41A and the lens 42A, the energy density at the focal point in the Y-direction is not so high, not causing a problem such as accumulation of dust.

A beam width in the Y-direction of the laser light L emitted from the light emitting element 32 and passing through the lens 41A and the lens 42A increases gradually in the X1-direction. The laser light L flared that expands in the Y-direction is input to the lens 43A via the lens 42A.

The optically functional portion of the lens 43A has, for example, a symmetrical shape about a virtual center plane as a plane intersecting and orthogonal to the Y-direction. The lens 43A has an input surface 43a and an output surface 43b each of which has a generatrix extending in the Z-direction and has a cylindrical surface extending in the Z-direction. The input surface 43a is a flat surface orthogonal to the X1-direction. In addition, the output surface 43b is a convex curved surface that bulges in the X1-direction.

The lens 43A collimates the laser light L in the Y-direction, that is, in the slow axis. The lens 43A is a convex lens in a cross-section orthogonal to the Z-direction. The lens 43A is also referred to as a collimation lens.

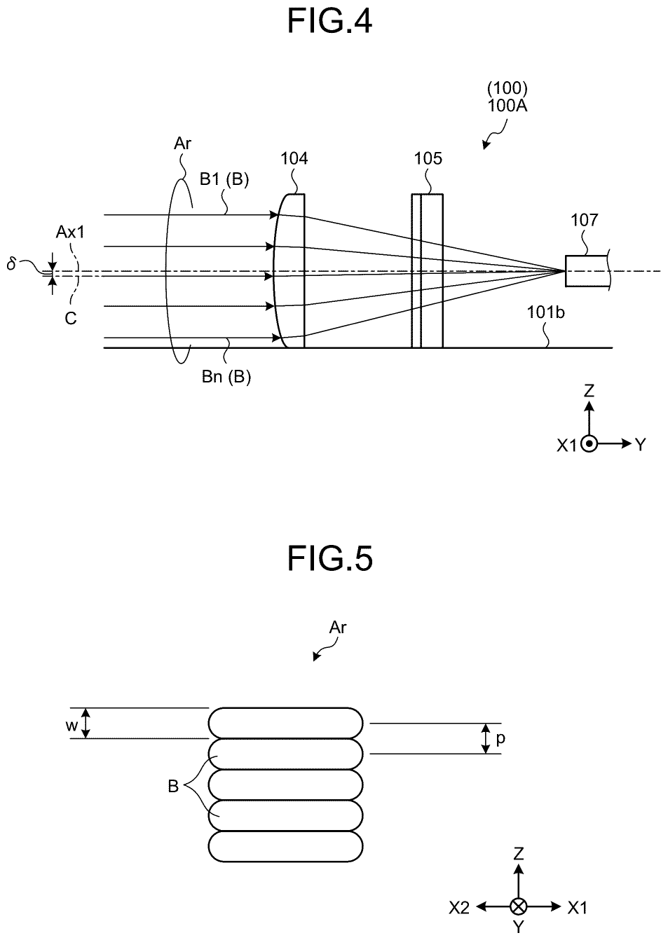

FIG. 4 is a side view illustrating optical paths of a plurality of laser beams B from the subunits 100a2 included in the array A2 (see FIG. 1) of the subunits 100a2, to the optical fiber 107 as the coupled portion via the condenser lenses 104 and 105. Note that each of the optical paths illustrated in FIG. 4 indicates a center axis (optical axis) of each of the beams B.

As described above, in the array A2 of the subunits 100a2, all of the plurality of laser beams B reflected by the mirrors 103 travel in the Y-direction, are arranged at substantially equal intervals in the Z-direction, and parallel to each other. As can be seen in FIGS. 1 and 2, the beam B is reflected by the mirror 103 having a larger distance from the condenser lens 104 in the Y-direction as the distance from the surface 101b in the Z-direction is larger. Here, the subunits 100a2 each have the same optical path length of the beam B, from the light emission unit 10A (light emitting element 32) to the mirror 103. Therefore, in the plurality of beams B illustrated in FIG. 4, as a beam B is farther from the surface 101b, in other words, as the beam B is farther from a beam Bn positioned at an end in a direction opposite to the Z-direction, in further other words, as the beam B is positioned further forward in the Z-direction (upward in FIG. 4), the optical path length from the light emission unit 10A to the condenser lens 104 is larger.

Furthermore, as described above, the laser light is output in the single mode in the fast axis direction and is output in the multi-mode in the slow axis direction, from the light emitting element 32. Here, in the range illustrated in FIG. 4, the fast axis direction of each of the laser beams B is in the Z-direction, and the slow axis direction is in the X1-direction and the X2-direction. In addition, the Y-direction as a direction in which an optical axis Ax1 of the condenser lens 104 extends and the beam B input to the condenser lens 104 travels is an example of a first direction, the Z-direction in which the beam B has the single mode is an example of a second direction, and the X1-direction and X2-direction in which the beam B has the multi-mode are examples of a third direction.

In such a configuration, the inventor has found that in an array Ar of the laser beams B illustrated in FIG. 4, as the distance of a beam B from the light emission unit 10A (light emitting element 32) to the condenser lens 104 is larger, that is, as the beam B is farther from the beam Bn, the coupling efficiency to the optical fiber 107 is smaller, reducing the overall coupling efficiency of the array Ar of the plurality of beams B to the optical fiber 107. It is estimated that this is because the beam width of the laser beam B output from the light emission unit 10A (light emitting element 32) is expanded larger in the directions in which the laser beam B has the multi-mode (the X1-direction and the X2-direction within the range illustrated in FIG. 4), as the optical path length from the light emission unit 10A (light emitting element 32) is increased.

Therefore, as illustrated in FIG. 4, the light emission device 100 of the present embodiment is configured so that a center line C positioned at the center of the array Ar of the plurality of beams B in the Z-direction is shifted in the direction opposite to the Z-direction relative to the optical axis Ax1 of the condenser lens 104. Specifically, for example, in the light emission device 100, the steps 101b1, the light emission units 10A, the subunits 100a, the mirrors 103, the condenser lens 104, the optical fiber 107, and the like are arranged to cause the shift as described above. Note that the center line C is an imaginary line that is positioned between an optical axis of a beam B1 positioned at an end in the Z-direction and an optical axis of the beam Bn positioned at the end in a direction opposite to the Z-direction and that extends in the Y-direction.

In the plurality of beams B passing through the condenser lens 104 that collects light in the Z-direction, the coupling efficiency to the optical fiber 107 decreases as the beam B is farther from the optical axis Ax1, and the coupling efficiency to the optical fiber 107 increases as the beam B is closer to the optical axis Ax1 due to the influence of the aberration of the condenser lens 104 or the like. Therefore, shifting the center line C in the direction opposite to the Z-direction relative to the optical axis Ax1 brings the beam B having a longer optical path length from the light emission unit 10A closer to the optical axis Ax1, and therefore, the coupling efficiency of the beam B to the optical fiber 107 may be increased. When the laser light has a wavelength of 400 [nm] or more and 550 [nm] or less, the width of the beam B tends to be easily increased. Therefore, shifting the center line C in the direction opposite to the Z-direction relative to the optical axis Ax1 is particularly effective when the wavelength of the laser light is 400 [nm] or more and 550 [nm] or less.

In addition, here, FIG. 4 illustrates the array Ar of the beams B is constituted by the laser beams B output from the plurality of light emission units 10A included in the array A2 of the subunits 100a2, but the array Ar may be constituted as in FIG. 4 by the laser beams B output from the plurality of light emission units 10A included in the array A1 of the subunits 100al, and shifting the center line C in the direction opposite to the Z-direction relative to the optical axis Ax1 may provide the effects similarly to the array A2 of the subunits 100a2.

FIG. 5 is a cross-sectional view of the array Ar of the beams B. As illustrated in FIG. 5, in the array Ar, the plurality of beams B has the same width w in the Z-direction and is arranged at substantially a constant pitch p in the Z-direction. For example, the pitch p is set to a value substantially the same as the width w. Note that the width w of the beam B is a width of a region having an optical intensity that is equal to or larger than a predetermined value in the beam profile of the laser light. The predetermined value is, for example, 1/e² of a peak optical intensity. Note that, in FIG. 5, all of the plurality of beams B in the X1-direction and the X2-direction are illustrated to have the same width, but actually, the width becomes larger as the beam B is positioned forward in the Z-direction (upward in FIG. 5).

The inventor has found, through experimental research on a deviation amount δ (see FIG. 4) of the center line C in the direction opposite to the Z-direction, that when the deviation amount δ exceeds w (≈p), that is, when the deviation is excessive, the coupling efficiency of the beam Bn(B) positioned at the end in the direction opposite to the Z-direction to the optical fiber 107 is reduced, and further, the overall coupling efficiency of all the beams B included in the array Ar to the optical fiber 107 is reduced. On the other hand, it has been found that when the deviation amount δ is less than 0.25w (≈0.25p), that is, when the deviation is insufficient, the coupling efficiency of the beam B1(B) positioned at the end in the Z-direction to the optical fiber 107 is reduced, and further, the overall coupling efficiency of all the beams B included in the array Ar to the optical fiber 107 is reduced. In other words, the inventor has found, through experimental research, that the deviation amount δ is preferably 0.25w or more and w or less, or 0.25p or more and p or less.

Furthermore, the inventor has found, through experimental research, that the deviation amount δ that maximizes the overall coupling efficiency of the plurality of beams B included in the array Ar to the optical fiber 107 is different between the array A1 of the subunits 100a1 and the array A2 of the subunits 100a2 within the range of the deviation amount δ of 0.25w or more and w or less. It is estimated that this is because an average value of the optical path lengths between the light emission units 10A belonging to the array A1 and the condenser lens 104 and an average value of the optical path lengths between the light emission units 10A belonging to the array A2 and the condenser lens 104 are different from each other. Therefore, the deviation amount δ is preferably set appropriately for each of the pluralities of light emission units 10A (hereinafter, referred to as light emission unit groups) that output the plurality of beams B constituting the array Ar. The plurality of light emission units 10A included in the subunits 100al is an example of a first light emission unit group, and the plurality of light emission units 10A included in the subunits 100a2 is an example of a second light emission unit group. Note that as described above, the polarization planes of the laser beams B from the plurality of light emission units 10A included in the subunits 100al and the polarization planes of the laser beams B from the plurality of light emission units 10A included in the subunits 100a2 are orthogonal to each other.

As described above, in the present embodiment, as illustrated in FIG. 4, the center line C of the array Ar in the Z-direction is shifted in the direction opposite to the Z-direction relative to the optical axis Ax1 of the condenser lens 104. With such a configuration, a beam B having a reduced coupling efficiency to the optical fiber 107 in the X1 direction and the X2 direction due to the long optical path length from the light emission unit 10A is positioned closer to the optical axis Ax1, and therefore, the coupling efficiency of the beam B to the optical fiber 107 may be increased in the Z direction, as compared with an array in which the center line C is not shifted relative to the optical axis Ax1. This configuration makes it possible to further increase the overall coupling efficiency of the array Ar of the plurality of beams B to the optical fiber 107.

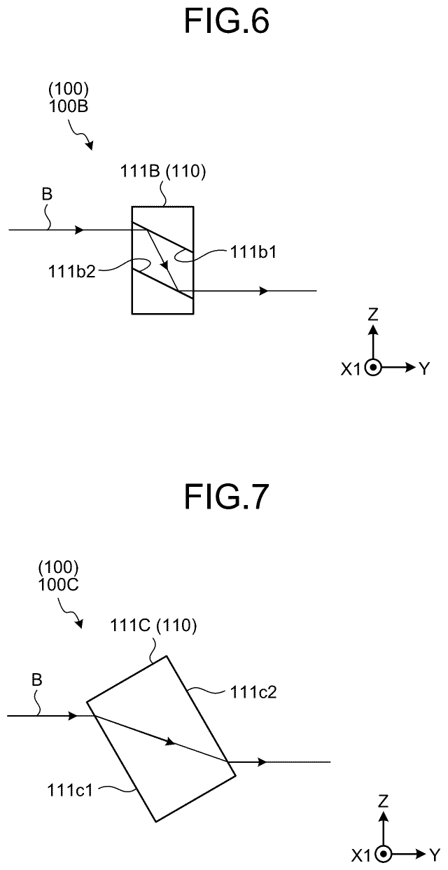

FIG. 6 is a side view of an optical system 110 included in a light emission device 100B (100) according to a second embodiment.

The optical system 110 illustrated in FIG. 6 is provided before the condenser lens 104, that is, between the light combining unit 108 and the condenser lens 104. The optical system 110 includes an optical component 111B, such as a dove prism, having two reflection surfaces 111b1 and 111b2. In this configuration, the optical system 110 reflects a laser beam B by the reflection surfaces 111b1 and 111b2 to shift the beam B traveling in the Y-direction in a direction opposite to the Z-direction and output the beam B in the Y-direction. Note that although only an optical path of one beam B is illustrated in FIG. 6, all beams B (see FIG. 4) included in the array Ar may pass through the optical system 110. In other words, the optical system 110 is configured to collectively shift all the beams B included in the array Ar in the direction opposite to the Z-direction.

Such a configuration makes it possible to add the optical system 110 before the condenser lens 104 to relatively readily shift the center line C of the array Ar in the Z-direction in the direction opposite to the Z-direction relative to the optical axis Ax1 of the condenser lens 104, without adjusting mutual arrangement of, for example, the steps 101b1, the light emission units 10A, the subunits 100a, the mirrors 103, the condenser lens 104, the optical fiber 107, and the like. In other words, according to the present embodiment, it is possible to relatively readily achieve a state having a higher overall coupling efficiency of the array Ar of the plurality of beams B to the optical fiber 107. In addition, by selectively providing an optical system 110 that provides a deviation amount δ giving a higher coupling efficiency, from a plurality of prepared optical systems 110 having different deviation amounts δ, against occurrence of manufacturing variations or the like, the state having a higher overall coupling efficiency may be relatively readily achieved.

Note that the optical component 111B may be implemented with various changes in specification. For example, the number of the reflection surfaces 111b1 and 111b2 may be three or more, or inclination angles of the reflection surfaces 111b1 and 111b2 relative to the Y-direction and the Z-direction may be different from those in the example of FIG. 6.

FIG. 7 is a side view of the optical system 110 included in a light emission device 100C (100) according to a third embodiment.

The optical system 110 illustrated in FIG. 7 is also provided before the condenser lens 104, that is, between the light combining unit 108 and the condenser lens 104. The optical system 110 is an optical component 111C, such as parallel plates, including two refraction surfaces 111c1 and 111c2 to transmit a beam B. In this configuration, the optical system 110 refracts a laser beam B by the refraction surfaces 111c1 and 111c2 to shift the beam B traveling in the Y-direction in the direction opposite to the Z-direction and output the beam B in the Y-direction. Note that although only an optical path of one beam B is illustrated in FIG. 7, all beams B (see FIG. 4) included in the array Ar may pass through the optical system 110. In other words, the optical system 110 is configured to collectively shift all the beams B included in the array Ar in the direction opposite to the Z-direction.

The present embodiment may also provide the effects similar to those of the second embodiment. In addition, according to the present embodiment, changing an inclination angle of the optical component 111C relative to the Z-direction or the Y-direction makes it possible to relatively readily change the deviation amount δ advantageously. Note that the optical component 111C may be implemented with various changes in specification, such as a thickness, length, or shape.

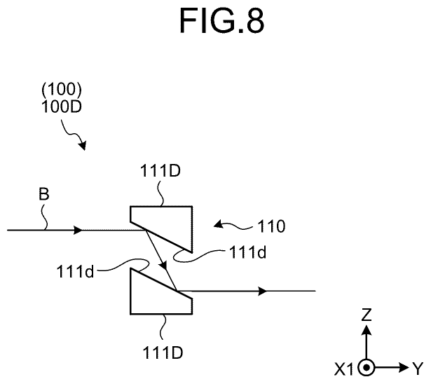

FIG. 8 is a side view of the optical system 110 included in a light emission device 100D (100) according to a fourth embodiment.

The optical system 110 illustrated in FIG. 8 is provided before the condenser lens 104, that is, between the light combining unit 108 and the condenser lens 104. The optical system 110 includes two optical components 111D such as mirrors each having a reflection surface 111d. In this configuration, the optical system 110 reflects a laser beam B by the two reflection surfaces 111d to shift the beam B traveling in the Y-direction in the direction opposite to the Z-direction and output the beam B in the Y-direction. Note that although only an optical path of one beam B is illustrated in FIG. 8, all beams B (see FIG. 4) included in the array Ar may pass through the optical system 110. In other words, the optical system 110 is configured to collectively shift all the beams B included in the array Ar in the direction opposite to the Z-direction.

The present embodiment may also provide the effects similar to those of the second embodiment. In addition, according to the present embodiment, changing the arrangement of the two optical components 111D makes it possible to relatively readily change the deviation amount δ advantageously. Note that the optical component 111D may be implemented with various changes in specification. For example, the number of the optical components 111D may be three or more, or inclination angles of the reflection surfaces 111d relative to the Y-direction and the Z-direction may be different from those in the example of FIG. 8.

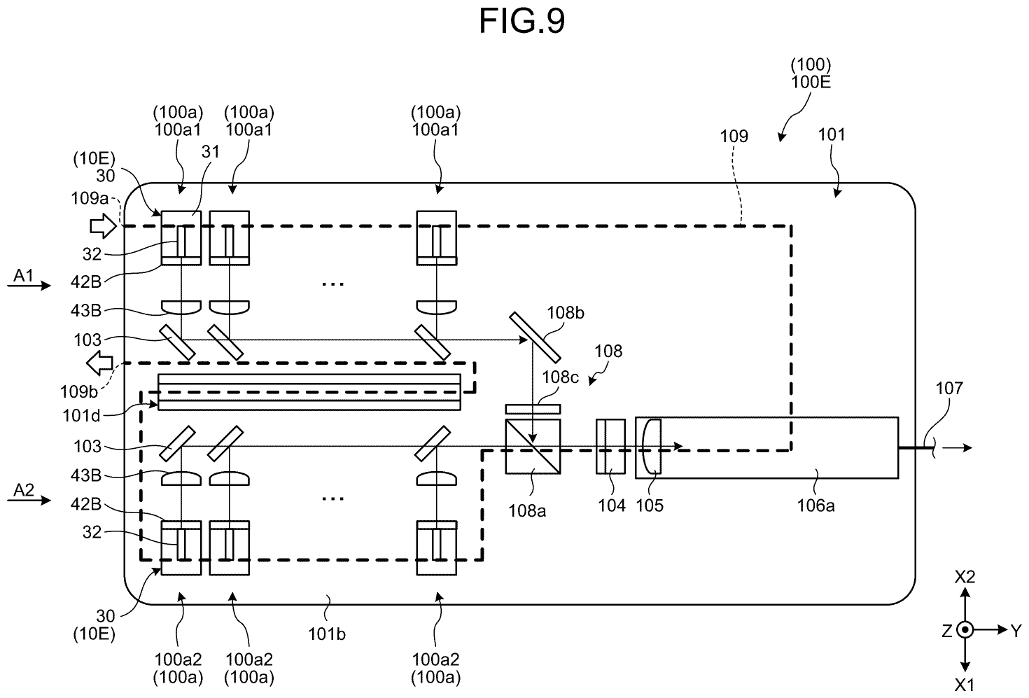

FIG. 9 is a plan view of a light emission device 100E (100) according to a fifth embodiment. The light emission device 100E has a configuration similar to that of the light emission device 100A (100) of the first embodiment except that the optical components of each subunit 100a have a different configuration.

In the present embodiment, the subunit 100a includes a light emission unit 10E, a lens 42B, a lens 43B, and the mirror 103. The light emission unit 10E does not include the case 20 (see FIG. 3) as in the first embodiment, but include the chip-on-submount 30. The chip-on-submount 30 is exposed in the storage chamber of the light emission device 100E. The lens 42B collimates laser light from the light emitting element 32 in the Z-direction, that is, along the fast axis. Furthermore, the lens 43B collimates the laser light from the lens 42B in the Y-direction, that is, along the slow axis.

In the present embodiment, adjusting mutual arrangement of the steps 101b1 (see FIG. 2), the light emission units 10E, the subunits 100a, the mirrors 103, the condenser lens 104, the optical fiber 107, and the like as in the first embodiment, or adding the optical system 110 as in the second to fourth embodiments before the condenser lens 104 also makes it possible to shift the center line C of the array Ar in the Z-direction in the direction opposite to the Z-direction relative to the optical axis Ax1 of the condenser lens 104, as in FIG. 4. In other words, the present embodiment may also provide the effects similar to those of the first to fourth embodiments.

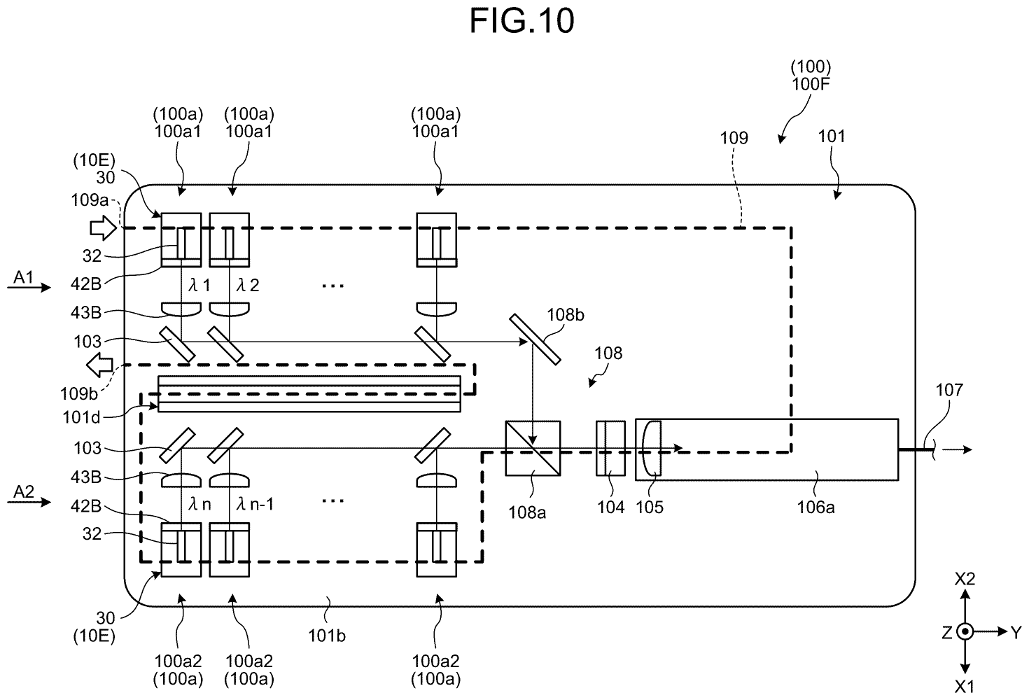

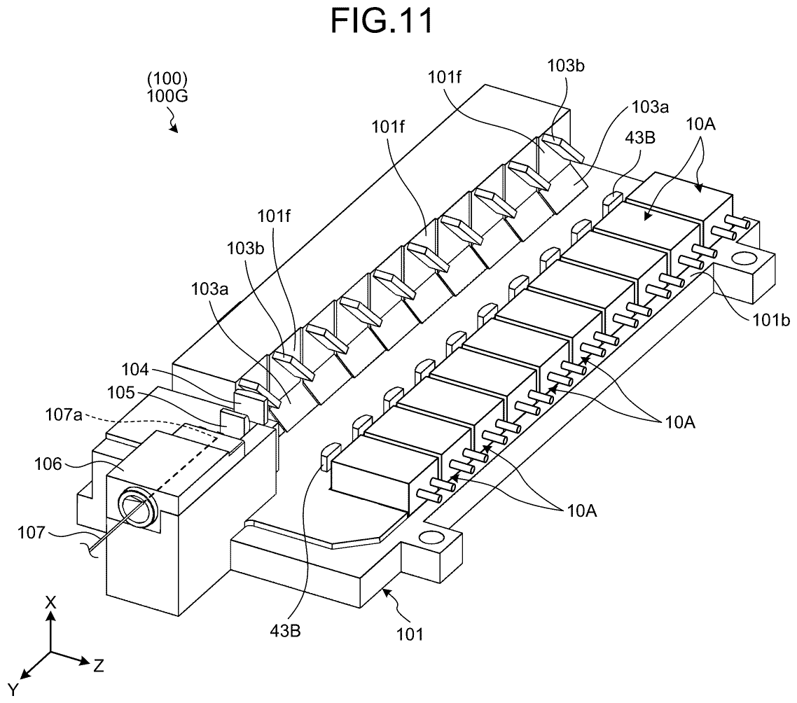

FIG. 10 is a plan view of a light emission device 100F (100) according to a sixth embodiment. The light emission device 100F has a configuration similar to that of the light emission device 100E of the fifth embodiment except that a plurality of the light emitting elements 32 output laser light having wavelengths (λ1, λ2, . . . , λn−1, and λn) different from each other and do not have the half wave plate 108c. A wavelength interval of a plurality of the wavelengths is, for example, 5 [nm] to 20 [nm] between center wavelengths. Furthermore, the light combined here may include blue laser light.

In the present embodiment, adjusting mutual arrangement of the steps 101b1 (see FIG. 2), the light emission units 10E, the subunits 100a, the mirrors 103, the condenser lens 104, the optical fiber 107, and the like as in the first embodiment, or adding the optical system 110 as in the second to fourth embodiments before the condenser lens 104 also makes it possible to shift the center line C of the array Ar in the Z-direction in the direction opposite to the Z-direction relative to the optical axis Ax1 of the condenser lens 104, as in FIG. 4. In other words, the present embodiment may also provide the effects similar to those of the first to fourth embodiments.

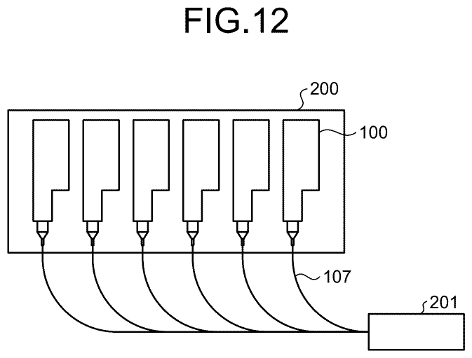

FIG. 11 is a perspective view of a light emission device 100G (100) according to a seventh embodiment. As illustrated in FIG. 11, in the present embodiment, the plurality of light emission units 10A is arranged on one surface 101b of the base 101 having a flat shape and having no step. Laser light from the plurality of light emission units 10A is arranged at equal intervals in the Y-direction.

Then, the light emitted in the direction opposite to the Z-direction from each light emission unit 10A through the lens 43B and the like is first reflected in the X-direction by a mirror 103a, then reflected in the Y-direction by a mirror 103b, and then directed to the condenser lens 104. Here, the base 101 has a plurality of side surfaces 101f (steps) that faces in the Z-direction and is arranged stepwise. Each of the side surfaces 101f intersects the Z-direction and extends in the X-direction and the Y-direction. The side surface 101f is shifted stepwise in the Z-direction toward a direction opposite to the Y-direction. Each of sets of the mirrors 103a and 103b optically connected is mounted on the side surface 101f. With such a configuration, the light traveling in the Y-direction from the mirrors 103b toward the condenser lens 104 is parallel to each other and arranged at equal intervals in the Z-direction, on an input surface to the condenser lens 104. The light from each light emission unit 10A is coupled to the optical fiber 107 via the condenser lenses 104 and 105.

In the present embodiment, laser beams input to the condenser lens 104 also have arrangement similar to the arrangement illustrated in FIG. 4. Therefore, according to the present embodiment, for example, as in the first embodiment, adjusting the mutual arrangement of the side surfaces 101f, the mirrors 103a and 103b, the condenser lens 104, the optical fiber 107, and the like makes it possible to shift the center line C of the array Ar in the Z-direction in the direction opposite to the Z-direction relative to the optical axis Ax1 of the condenser lens 104. Furthermore, also in the present embodiment, adding the optical system 110 as in the second to fourth embodiments before the condenser lens 104 makes it possible to shift the center line C of the array Ar in the Z-direction in the direction opposite to the Z-direction relative to the optical axis Ax1 of the condenser lens 104. In other words, the present embodiment may also provide the effects similar to those of the first to fourth embodiments.

FIG. 12 is a configuration diagram of a light source device 200 according to an eighth embodiment on which the light emission device 100 of any of the first to seventh embodiments is mounted. The light source device 200 includes a plurality of light emission devices 100 as a pumping light source. Laser light output from the plurality of light emission devices 100 is transmitted to a combiner 201 as an optical coupling unit via the optical fibers 107. The optical fibers 107 have output ends that are coupled to a plurality of input ports of the combiner 201 that is a multi-input single-output combiner. Note that the light source device 200 is not limited to a light source device including the plurality of light emission devices 100 as long as at least one light emission device 100 is included.

According to the light source device 200 of the present embodiment, the light emission devices 100 of the first to seventh embodiments may be included to provide effects similar to those of the first to seventh embodiments.

Although the embodiments have been described above, the above embodiments are merely examples, and the scope of the disclosure is not intended to be limited. The above embodiments may be implemented in various other forms, and various omissions, substitutions, combinations, and changes may be made without departing from the spirit of the disclosure. Furthermore, specifications (structure, type, direction, model, size, length, width, thickness, height, quantity, arrangement, position, material, etc.) of each configuration, shape, and the like may be appropriately changed and carried out.

According to the present disclosure, the improved novel light emission device and the light source device may be obtained.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A light emission device comprising:
a condenser lens having an optical axis extending in a first direction, the condenser lens being configured to collect light in a second direction orthogonal to the first direction, wherein an array of a plurality of light beams traveling in the first direction and arranged at intervals in the second direction is input to the condenser lens; and
a light emission unit group including a plurality of light emission units configured to output the beams included in the array, each of the light emission units being configured to output each of the beams in a single mode in the second direction and in a multi-mode in a third direction orthogonal to the first direction and the second direction, wherein an optical path length between the condenser lens and the light emission unit outputting the beam is longer as the beam output from the light emission unit is farther from the beam positioned at an end of the array in a direction opposite to the second direction,
wherein a center line positioned at a center in the second direction of the array of the beams output from the plurality of light emission units included in the light emission unit group is shifted in a direction opposite to the second direction relative to the optical axis of the condenser lens.

2. The light emission device according to claim 1, wherein
the light emission unit group includes a plurality of light emission unit groups different in an average value of the optical path lengths between the plurality of light emission units included in each light emission unit group and the condenser lens, and
a deviation amount of the center line relative to the optical axis is different between the plurality of light emission unit groups.

3. The light emission device according to claim 2, wherein
the plurality of light emission unit groups includes a first light emission unit group and a second light emission unit group, and
a polarization plane of light included in the array corresponding to the plurality of light emission units included in the first light emission unit group and a polarization plane of light included in the array corresponding to the second light emission unit group are orthogonal to each other.

4. The light emission device according to claim 1, wherein the light emission unit group includes the plurality of light emission units arranged in an array.

5. The light emission device according to claim 1, wherein the plurality of light emission units included in the light emission unit group are arranged to be shifted from each other in the second direction.

6. The light emission device according to claim 1, further comprising an optical system configured to
shift a plurality of light beams output from the plurality of light emission units included in the light emission unit group and traveling on an optical path orthogonal to the second direction in the direction opposite to the second direction, and
output the plurality of light beams in a direction orthogonal to the second direction.

7. The light emission device according to claim 6, wherein the optical system includes an optical component having a plurality of reflection surfaces.

8. The light emission device according to claim 6, wherein the optical system includes an optical component having a plurality of refraction surfaces.

9. The light emission device according to claim 6, wherein the optical system includes a plurality of optical components each having a reflection surface.

10. The light emission device according to claim 1, wherein when a width of a light beam output from each of the plurality of light emission units included in the light emission unit group is w, a deviation amount of the center line corresponding to the light emission unit group relative to the optical axis of the condenser lens is 0.25w or more and w or less.

11. The light emission device according to claim 1, wherein light output from the light emission unit has a wavelength of 400 nm or more and 550 nm or less.

12. A light source device comprising the light emission device according to claim 1.
